(19) United States
(12) Patent Application Publication
(10) Pub. No.: US 2018/0073147 A1
(43) Pub. Date: Mar. 15, 2018

(54) REMOTE PLASMA GENERATOR OF REMOTE PLASMA-ENHANCED CHEMICAL VAPOR DEPOSITION (PECVD) SYSTEM

(71) Applicant: Yu-Shun CHANG, Taipei City (TW)

(72) Inventor: Yu-Shun CHANG, Taipei City (TW)

(21) Appl. No.: 15/413,899

(22) Filed: Jan. 24, 2017

(30) Foreign Application Priority Data
Sep. 13, 2016 (TW) 105129774

(51) Int. Cl. C23C 16/511; C23C 16/505; C23C 16/503; C23C 16/46; C23C 16/455

(52) U.S. Cl. CPC C23C 16/511; C23C 16/505; C23C 16/455; C23C 16/46; C23C 16/503

(57) ABSTRACT

A remote plasma generator of a remote plasma-enhanced chemical vapor deposition (PECVD) system is revealed. A direct current (DC) discharge unit, a radiofrequency (RF) discharge unit and a microwave discharge unit are arranged at the remote plasma generator separately. Source materials or process gas introduced into the remote plasma generator are/is excited by synchronous discharging of the DC discharge unit, the RF discharge unit and the microwave discharge unit to generate a plasma source required. The efficiency in use and the efficiency in manufacturing process of the remote PECVD are improved.

### BACKGROUND OF THE INVENTION

The present invention relates to a plasma generator, especially to a remote plasma generator of a remote plasma-enhanced chemical vapor deposition (PECVD) system in which a direct current (DC) discharge unit, a radiofrequency (RF) discharge unit and a microwave discharge unit are arranged separately. The process gas introduced into the remote plasma generator is excited by synchronous discharging of the DC discharge unit, the RF discharge unit and the microwave discharge unit so as to generate a plasma source required.

Chemical vapor deposition (CVD) is a technique for depositing a thin film of materials on surface of substrates. Source materials (also called film precursors, reaction sources) in gas form (called main gas) are introduced into a reaction chamber to carry out chemical reactions such as oxidation, reduction on a substrate surface. Then the product is deposited on the substrate surface to form the thin film by internal diffusion.

Plasma has been widely applied to various fields. For example, growth of films made from different materials or circuit etching in semiconductor manufacturing is achieved by using plasma. The plasma includes chemically active ions and radicals and the substrate surface hit by ions also has higher chemical activity. Thus the chemical reaction rate of the substrate surface is accelerated. PECVD (Plasma-enhanced CVD) is a specific type of CVD. PECVD has a wide variety of applications, being used to form thin film of oxide and nitride. PECVD is similar to CVD and having a great advantage over CVD that the deposition can occur at lower temperature. Moreover, there is a remote plasma-enhanced CVD (RPECVD) in which the substrate is not directly in the plasma discharge region. A plasma generator is arranged separately from a reaction chamber and is called a remote plasma generator. Gaseous source materials are introduced into the plasma generator first to generate plasma by microwave or radiofrequency power. Then the plasma is introduced into the reaction chamber for the following film deposition process.

There is a plurality of related prior arts in the field of CVD, PECVD, and remote PECVD including U.S. Pat. No. 5,908,602, U.S. Pat. No. 6,444,945, US App. No. 2006/0177599, U.S. provisional App. No. 61/137,839 (TWI532414), etc. Most of the conventional PECVD devices are used in small-scale deposition (smaller than m²) because that the plasma sources are only suitable for small area coating. In U.S. Pat. No. 6,444,945, a plasma source includes a structure made up of two hollow cathode shapes connected to a bipolar AC power supply is revealed. Yet more energy is consumed so that the production cost is increased. Refer to US. Pat. App. No. 61/137,839, it provides novel linear and two dimensional plasma sources that produce linear and two dimensional plasmas, respectively, that are useful for plasma-enhanced chemical vapor deposition.

The plasma source plays a key role in the PECVD system. There is a plurality of ways used to generate the plasma including direct current discharge, low frequency and intermediate frequency discharge, radiofrequency (RF) discharge and microwave discharge. However, the plasma generator of the conventional remote PECVD system has the following shortcomings. First the way of the plasma generator used to generate the plasma source has been set in advance. The plasma generator usually uses one of the following ways including direct current (DC) discharge, radiofrequency (RF) discharge, and microwave discharge to generate the plasma source. Thus process gas, source materials (film precursors) or deposited materials used and the film formed are limited. Different deposited materials can't be applied to the plasma generator using specific way to generate plasma. Secondly the plasma generator of the conventional PECVD system is usually disposed with on process gas inlet. Thus the sources materials (also called film precursors, reaction sources) used are restricted and only one layer of deposited material is produced during one deposition process. The efficiency in manufacturing process of the remote PECVD system is reduced. The plasma source generated in a cavity of the plasma generator may be unable to meet requirements of the remote PECVD process when the plasma-generating method of the plasma generator of the remote PECVD system has been limited to DC discharge, RF discharge, or microwave discharge. For example, the problem of lower plasma density or poor uniformity of the plasma distributed in the space may occur owing to ineffective control of the plasma density. The efficiency in the manufacturing process of the remote PECVD system is further lowered.

Thus there is room for improvement and there is a need to provide a novel remote plasma generator of a remote PECVD system that not only improves quality of the plasma source in the plasma generator but also increases the process efficiency of the remote PECVD system.

### SUMMARY OF THE INVENTION

Therefore it is a primary object of the present invention to provide a remote plasma generator of a remote plasma-enhanced chemical vapor deposition (PECVD) system that includes a direct current (DC) discharge unit, a radiofrequency (RF) discharge unit and a microwave discharge unit arranged separately. The DC discharge unit, the RF discharge unit, and the microwave discharge unit discharge at the same time to activate process gas introduced into the remote PECVD system and generate a plasma source required. Thereby the efficiency in use and the efficiency in manufacturing process of the remote PECVD system are further increased.

In order to achieve the above object, a remote plasma generator of a remote plasma-enhanced chemical vapor deposition (PECVD) system according to the present invention includes three kinds of discharge unit—a direct current (DC) discharge unit, a radiofrequency (RF) discharge unit and a microwave discharge unit arranged separately. The power of the DC is 17 KVA/m±20%. The frequency and field strength of the RF discharge unit is 12000 MHZ 130 A/m±6%. The RF power of the microwave discharge unit is 150 db/w. The three kinds of discharge unit discharge at the same time to activate source materials (also called film precursors, reaction sources)/or process gas introduced into the remote PECVD system and generate plasma sources required while the remote PECVD system works. Thereby the efficiency in use and the efficiency in manufacturing process of the remote PECVD are both improved.

The remote plasma generator further uses argon (Ar) of inert gas as the process gas. The introduced rate of the argon gas is set within a range of 3˜20 cc/min. Thus the plasma source required is generated.

The number of the process gas inlet on the remote plasma generator is not limited. The remote plasma generator can include two or three process inlets so that the number of kinds of source materials or process gas in a deposition process is increased and at least one deposition layer can be produced at once by one deposition process.

### BRIEF DESCRIPTION OF THE DRAWINGS

FIG. 1 is a longitudinal sectional view of an embodiment of a remote plasma generator of a remote plasma-enhanced chemical vapor deposition (PECVD) system according to the present invention;

FIG. 2 is a longitudinal sectional view of an embodiment of a remote plasma generator according to the present invention.

### DETAILED DESCRIPTION OF THE PREFERRED EMBODIMENTS

In order to learn structure and technical features of the present invention, please refer to the following embodiments and the related figures. Each component in the figures is not drawn to scale.

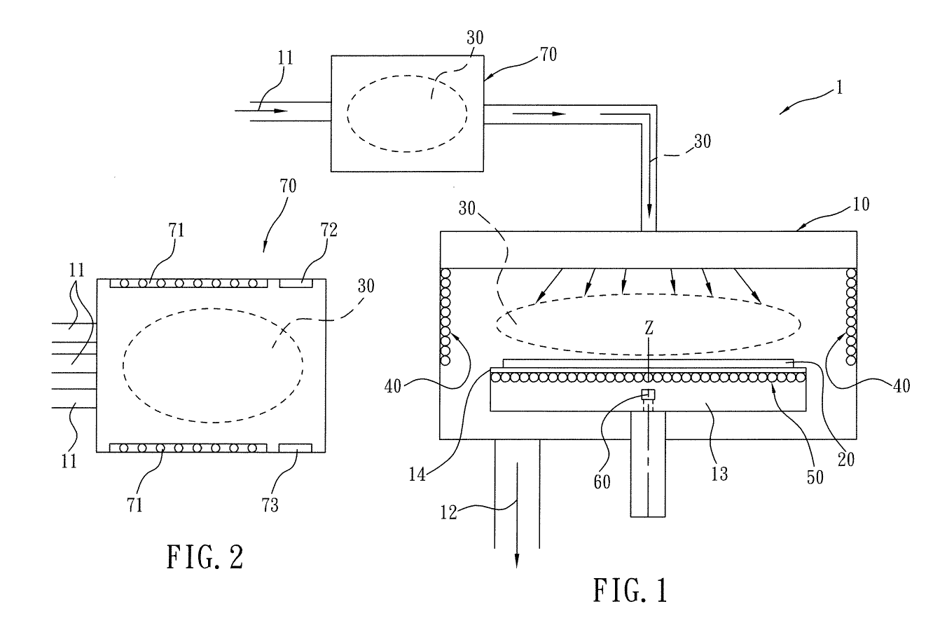

Refer to FIG. 1, a remote plasma generator 70 of the present invention is applied to a remote plasma-enhanced chemical vapor deposition (PECVD) system 1. The remote PECVD) system 1 can be, but not limited to a conventional PECVD system 1. The remote PECVD system 1 includes a reaction chamber 10 and a remote plasma generator 70. The reaction chamber 10 consists of a process gas inlet 11, a by-product outlet 12, a platform 13, and a platform surface 14. The process gas includes source materials (also called reaction sources or film precursors) in gas form. The gas by-products are drawn out of the reaction chamber 10 through the by-product outlet 12 by a vacuum pump. The platform 13 is used for heating while the platform surface 14 is set on the platform 13 and used for loading at least one substrate 20. The process gas inlet 11 is connected to the remote plasma generator 70 for introducing the source materials or the process gas into the remote plasma generator 70 to generate a plasma source 30. Then the plasma source 30 is introduced into the reaction chamber 10 for performing a film deposition process.

Refer to FIG. 2, a remote plasma generator 70 of the remote plasma-enhanced chemical vapor deposition (PECVD) system 1 features on that the remote plasma generator 70 is disposed with a radiofrequency (RF) discharge unit 71, a direct current (DC) discharge unit 72, and a microwave discharge unit 73 respectively. The RF discharge unit 71, the DC discharge unit 72 and the microwave discharge unit 73 discharge synchronously while the remote PECVD system works to excite source materials or process gas and generate a plasma source 30 that meets users' requirements. Thereby the efficiency in use and the efficiency in process are further improved. In FIG. 2, the position and/or structure of the RF discharge unit 71, the DC discharge unit 72 and the microwave discharge unit 73 are not drawn to scale. The RF discharge unit 71, the DC discharge unit 72 and the microwave discharge unit 73 can be arranged properly by electronic techniques available now.

In an embodiment of the remote plasma generator 70 of the present invention, the frequency and field strength of the RF discharge unit 71 is set at 12000 MHZ 130 A/m±6%. The power of the DC discharge unit 72 is set at 17 KVA/m±20%. The RF power of the microwave discharge unit 73 is set at 150 db/w. Thereby an ideal plasma source 30 required is generated by activation of source materials (also called film precursors, reaction sources)/or process gas in the remote plasma generator 70 resulted from discharging of the discharge units set with the above power source data.

In an embodiment of the remote plasma generator 70 of the present invention, the remote plasma generator 70 further uses argon (Ar) of inert gas as the process gas to generate argon plasma. The introduced rate of the argon gas is set within a range of 3˜20 cc/min. Thus the remote plasma generator 70 can generate a better plasma source 30 that users need.

In an embodiment of the remote plasma generator 70 of the present invention, the remote plasma generator 70 is disposed with at least one process gas inlet 11. The number of the process gas inlet 11 set on the remote plasma generator 70 is not limited. Refer to FIG. 2, there are three process gas inlets 11 set on the remote plasma generator 70 for introducing different source materials (also called film precursors, reaction source) or process gas. Thus the number of kinds of source materials or process gas in a deposition process is increased and at least one deposition layer can be produced at once by one deposition process.

For being used in combination with the remote plasma generator 70 and improvement of the process efficiency of the remote PECVD system, the reaction chamber 10 is disposed with at least one auxiliary device that includes at least one electric field device. The electric field device is a first electric field device 40 disposed around an inner wall of the reaction chamber 10, as shown in FIG. 1. The first electric field device 40 generates an electric field by using radiofrequency (RF) current flowing through a coil. Then the electric field formed provides electrical attraction to the plasma source 30 in the reaction chamber 10 so that source materials or film precursors in the plasma source 30 are diffused and moved from a center of the reaction chamber 10 (as the Z axis indicates in FIG. 1) toward the inner wall around the reaction chamber 10 before being attached and deposited on at least one surface of the substrate 20 to form the film. Thus uniformity of the film formed is improved. In this embodiment, the RF current flowing through the coil and used by the first electric field device 40 varies according to density of the source material. For example, the RF can be, but not limited to, 700 v/m±6%, 1300 v/m±6%, or 1900 v/m±6%.

Moreover, the auxiliary device of the reaction chamber 10 further includes a second electric field device 50 arranged under the platform surface 14 of the reaction chamber 10. The second electric field device 50 also generates an electric field by using RF current flowing through a spiral coil (wound around the Z axis as shown in FIG. 1). The electric field formed by the second electric field device 50 also provides electrical attraction to the plasma source 30 in the reaction chamber 10 so that the source materials or the film precursors in the plasma source 30 are attached and deposited on at least one surface of the substrate 20 by the electrical attraction. While in use, the electric field effect of the first electric field device 40 is off first and then the electric field effect of the second electric field device 50 is on. That means the first electric field device 40 and the second electric field device 50 are arranged and operated separately. After the second electric field device 50 being turned on, the plasma source 30 in the reaction chamber 10 is under electrical attraction of the electric field formed and source materials or film precursors in the plasma source 30 is forced to be attached to or deposited on at least one surface of the substrate 20 faster. Thus the thickness of the film deposited can be controlled and reduced effectively. In this embodiment, the second electric field device 50 generates an electric field by using RF current passed through a spiral coil wound around the Z axis. The RF used varies according to concentration of the source material in gas form. For example, the RF can be, but not limited to, 90 uv/m+4.5%, 500 uv/m±4.5%, or 1100 uv/m±4.5%.

Furthermore, the auxiliary device for the reaction chamber 10 further includes a RF magnetic field device 60 that is arranged under a center (as the Z axis in FIG. 1 indicates) of the platform surface 14 of the reaction chamber 10 and used for control of an angle of epitaxy deposited on the surface of the substrate 20.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A remote plasma generator of a remote plasma-enhanced chemical vapor deposition (PECVD) system comprising:
a direct current (DC) discharge unit,
a radiofrequency (RF) discharge unit; and
a microwave discharge unit arranged separately;
wherein the DC discharge unit, the RF discharge unit, and the microwave discharge unit discharge simultaneously to activate process gas in the remote plasma generator for generating a plasma source while the remote PECVD system works;
wherein the PECVD system further includes a reaction chamber; the reaction chamber having at least one process gas inlet for introducing process gas containing source materials or film precursors in gas form, a by-product outlet through which gas by-products are drawn out of the reaction chamber, a platform used for heating, and a platform surface set on the platform and used for loading at least one substrate; wherein the process gas inlet is connected to the remote plasma generator for introducing the process gas into the remote plasma generator to generate the plasma source; then the plasma source is introduced into the reaction chamber for performing a film deposition process.

2. The device as claimed in claim 1, wherein frequency and field strength of the RF discharge unit is set at 12000 MHZ 130 A/m±6%.

3. The device as claimed in claim 1, wherein power of the DC discharge unit is set at 17 KVA/m±20%.

4. The device as claimed in claim 1, wherein RF power of the microwave discharge unit is set at 150 db/w.

5. The device as claimed in claim 1, wherein the remote plasma generator further uses argon (Ar) as the process gas; an introduced rate of the argon gas is set within a range of 3˜20 cc/min.

6. The device as claimed in claim 1, wherein the remote plasma generator is disposed with at least two process gas inlets for introducing different kinds of process gas.

7. The device as claimed in claim 1, wherein the reaction chamber of the PECVD system is disposed with a first electric field device set around an inner wall thereof; the first electric field device generates an electric field by using radiofrequency (RF) current flowing through a coil; the electric field formed provides electrical attraction to the plasma source in the reaction chamber so that source materials in the plasma source are diffused and moved from a center of the reaction chamber to the inner wall around the reaction chamber before being attached and deposited on at least one surface of the substrate to form the film; wherein the RF used by the first electric field device varies according to densities of the source materials.

8. The device as claimed in claim 7, wherein the RF is selected from the group consisting of 700 v/m±6%, 1300 v/m±6%, and 1900 v/m±6%.

9. The device as claimed in claim 1, wherein the reaction chamber of the remote PECVD system is further disposed with a second electric field device arranged under the platform surface of the reaction chamber; the second electric field device generates an electric field by using radiofrequency (RF) current flowing through a spiral coil; the electric field formed by the second electric field device provides electrical attraction to the plasma source in the reaction chamber so that the source materials in the plasma source are attached and deposited on at least one surface of the substrate by the electrical attraction; wherein the RF varies according to concentration of the source materials in gas form.

10. The device as claimed in claim 7, wherein the RF is selected from the group consisting of 90 uv/m±4.5%, 500 uv/m±4.5%, and 1100 uv/m 4.5%.

11. The device as claimed in claim 1, wherein The device as claimed in claim 1, wherein the reaction chamber of the remote PECVD system is further disposed with a radiofrequency (RF) magnetic field device; the RF magnetic field device is arranged under a center of the platform surface of the reaction chamber and used for control of an angle of epitaxy deposited on at least one surface of the substrate.
